(19) United States
(12) Patent Application Publication
(10) Pub. No.: US 2010/0244196 A1
(43) Pub. Date: Sep. 30, 2010

(54) Group III nitride semiconductor composite substrate, group III nitride semiconductor substrate, and group III nitride semiconductor composite substrate manufacturing method

(75) Inventor: Takehiro Yoshida, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 12/458,209

(22) Filed: Jul. 2, 2009

(30) Foreign Application Priority Data
Mar. 30, 2009 (JP) 2009-081337

(51) Int. Cl. H01L 29/20; H01L 21/18

(52) U.S. Cl. 257/615; 438/455; 257/E29.089; 257/E21.088

(57) ABSTRACT

A group III nitride semiconductor composite substrate includes a substrate composed of a conductive material having a melting point of not less than 100° C., a group III nitride layer provided on the substrate, and a group III nitride single crystal film provided on the group III nitride layer. The group III nitride layer includes an undulation including a periodic roughness in a surface of the group III nitride layer contacted with the group III nitride single crystal film. The undulation includes a 1-dimensional power spectral density of less than 500 nm³ in the spatial wavelength region of not less than 0.1 (/μm) and less than 1 (/μm).

The present application is based on Japanese patent application No. 2009-081337 filed on Mar. 30, 2009, the entire contents of which are incorporated herein by reference.

### BACKGROUND OF THE INVENTION

1. Field of the Invention

The present invention relates to a group III nitride semiconductor composite substrate, a group III nitride semiconductor substrate, and a group III nitride semiconductor composite substrate manufacturing method. In particular, it relates to a group III nitride semiconductor composite substrate, a group III nitride semiconductor substrate, and a group III nitride semiconductor composite substrate manufacturing method, capable of being used in semiconductor devices.

2. Description of the Related Art

Conventionally, a GaN layer-formed sapphire substrate fusion technique is known that cuts a sapphire substrate with a GaN layer formed thereon to form and prepare plural 4 mm×5 mm sized cut pieces, and causes the GaN layers of the 2 cut pieces to face and closely contact each other, followed by heat treatment in a nitrogen or hydrogen atmosphere, to thereby fuse both cut pieces.

The above technique causes voids at the laminated interface when the root mean square (RMS) of surface roughness within a 1 μm×1 μm range of cut piece surface before laminating is 26 angstroms, but no voids when the RMS is 10 angstroms.

Refer to T. Tokuda, et al. Japanese Journal of Applied Physics, 39 (2000), L572, for example.

However, the above technique examines as small pieces as on the order of 4 mm×5 mm, but takes no account of long period roughness in large area wafer surface and may therefore cause voids at the laminated interface when using a wafer with a no less than 50.8 mm (2 inch)-diameter area.

### SUMMARY OF THE INVENTION

Accordingly, it is an object of the present invention to provide a group III nitride semiconductor composite substrate, a group III nitride semiconductor substrate, and a group III nitride semiconductor composite substrate manufacturing method, capable of inhibiting the occurrence of voids at a laminated interface between group III nitride semiconductor layers.
(1) According to one embodiment of the invention, a group III nitride semiconductor composite substrate comprises:

a substrate comprising a conductive material having a melting point of not less than 1100° C.;

a group III nitride layer provided on the substrate; and

a group III nitride single crystal film provided on the group III nitride layer,

wherein the group III nitride layer comprises an undulation comprising a periodic roughness in a surface of the group III nitride layer contacted with the group III nitride single crystal film, and

the undulation comprises a 1-dimensional power spectral density of less than 500 nm³ in a spatial wavelength region of not less than 0.1 (/μm) and less than 1 (/μm).

In the above embodiment (1), the following modifications and changes can be made.

(i) The group III nitride single crystal film comprises an undulation comprising a periodic roughness in a surface of the group III nitride single crystal film contacted with the group III nitride layer, and the undulation comprises a 1-dimensional power spectral density of less than 500 nm³ in a spatial wavelength region of not less than 0.1 (/μm) and less than 1 (/μm).

(ii) The substrate comprises a material selected from a group consisting of tungsten, molybdenum, tantalum, niobium, vanadium, nickel, titanium, chromium, and zirconium, and

the group III nitride layer and the group III nitride single crystal film each comprises a group III nitride compound semiconductor having a composition expressed by AlₓIn_{y}Ga_{1-x-y}N (0≦x≦1, 0≦y≦1, 0≦x+y≦1).

(iii) The group III nitride semiconductor composite substrate comprises:

a diameter of not less than 2 inches.
(2) According to another embodiment of the invention, a group III nitride semiconductor substrate comprises:

a frontside surface and a backside surface,

wherein either or both of the frontside surface and the backside surface comprise an undulation comprising a periodic roughness, and

the undulation comprises a 1-dimensional power spectral density of less than 500 nm³ in a spatial wavelength region of not less than 0.1 (/μm) and less than 1 (/μm).

In the above embodiment (2), the following modifications and changes can be made.

(iv) The group III nitride semiconductor substrate comprises a group III nitride compound semiconductor having a composition expressed by AlₓIn_{y}Ga_{1-x-y}N (0≦x≦1, 0≦y≦1, 0≦x+y≦1).
(3) According to another embodiment of the invention, a group III nitride 2 0 semiconductor composite substrate manufacturing method comprises:

preparing a substrate comprising a group III nitride layer;

grinding a surface of the group III nitride layer of the substrate;

preparing a group III nitride single crystal;

grinding a surface of the group III nitride single crystal;

implanting atoms from a surface of the group III nitride single crystal into the group III nitride single crystal, to thereby form a damaged layer inside the group III nitride single crystal; and

fusing the ground surface of the group III nitride layer of the substrate, and the ground surface of the group III nitride single crystal,

wherein the ground surface of the group III nitride layer, and the ground surface of the group III nitride single crystal each comprise an undulation comprising a periodic roughness, and

the undulation comprises a 1-dimensional power spectral density of less than 500 nm³ in a spatial wavelength region of not less than 0.1 (/μm) and less than 1 (/μm).

Points of the Invention

According to one embodiment of the invention, the group III nitride composite substrate is formed with an undulation that has a 1-dimensional power spectral density of less than 500 nm³ in a spatial wavelength region of not less than 0.1 (/μm) and less than 1 (/μm) both on the surface of the group III nitride layer and the surface of the group III nitride single crystal film. By thus controlling the 1-dimensional power spectral density of the undulation in the spatial wavelength region of not less than 0.1 (/μm) and less than 1 (/μm), the occurrence of voids at the laminated interface can be reduced. This allows separation at the laminated interface to be inhibited even if mechanically processing, e.g., grinding the group III nitride composite substrate, and also even if increasing/decreasing the temperature between room temperature and a high temperature, e.g., 1000° C.

### BRIEF DESCRIPTION OF THE DRAWINGS

The preferred embodiments according to the invention will be explained below referring to the drawings, wherein:

FIG. 1 is a schematic view showing a group III nitride composite substrate in an embodiment according to the invention;

FIGS. 2A-2D are diagrams showing a flow for manufacturing a group III nitride composite substrate in an embodiment according to the invention;

FIGS. 3A and 3B are diagrams showing a flow for manufacturing a group III nitride composite substrate in an embodiment according to the invention; and

FIG. 4 is a diagram showing results of power spectral density analysis of group III nitride composite substrates in Examples and Comparative Examples.

### DETAILED DESCRIPTION OF THE PREFERRED EMBODIMENTS

Knowledge Gained by the Inventor

A group III nitride composite substrate as a group III nitride semiconductor composite substrate in this embodiment can be realized from knowledge based on below-described experiments done by the inventor.

First, the inventor prepares a gallium nitride (GaN) epitaxial wafer on a 2 inch diameter sapphire substrate, and a 2 inch diameter GaN single crystal substrate. The surface of the GaN epitaxial wafer on the sapphire substrate, and surface of the GaN single crystal substrate are cleaned with an organic solvent. Here, the root mean square (RMS) roughness in a 10 μm×10 μm range of the GaN single crystal substrate is 5 angstroms, while the RMS roughness in a 10 μm×10 μm range of the surface of the GaN epitaxial wafer on the sapphire substrate is 8 angstroms.

Subsequently, the flat surface of the GaN epitaxial wafer on the sapphire substrate, and the flat surface of the GaN single crystal substrate are closely contacted, followed by heat treatment in a nitrogen or hydrogen gas atmosphere at 1000° C. for 30 min with 50 kgf/cm² force applied to the close contact surface. This results in a composite substrate with the laminated GaN epitaxial wafer and GaN single crystal substrate therein. However, when this composite substrate is cut, many void defects are observed in a section thereof at the laminated interface. The inventor has repeated the same experiment many times, and has thereby verified that there are cases of many void defects and not so many void defects observed at the laminated interface.

With various methods, the inventor has evaluated and compared the cases of many void defects and not so many void defects observed at the laminated interface of the composite substrate (herein, referred to as “the cases of failure and success” respectively) to find out a cause thereof. As a result, it has been found that the cause is that in the cases of failure and success, a significant difference arises in “power spectra” in the wafer surfaces.

The power spectrum is a power spectral density plotted as a function of spatial frequency of surface roughness, where the power spectral density is the power (=roughness amplitude squared) divided by roughness spatial frequency (=inverse roughness wavelength). Thus, the dimension of the power spectral density is the cube of length. The power spectrum of surface shape of a wafer can be obtained by Fourier transform of results of measuring surface roughness shape of the wafer with a measuring instrument such as an Atomic Force Microscope (AFM). The analysis method for obtaining a power spectral density of the wafer surface allows elucidation of the presence of roughness shape which occurs periodically in the wafer surface, and which is likely to be missed as random shape with other analysis methods.

That is, the inventor has found that void defects at the laminated interface can be reduced by controlling the “power spectrum” in the wafer surface. Thus, below-described embodiments according to the invention are based on such knowledge.

The power spectral density in this embodiment employs 1-dimensional power spectral density. The reason for this is because of Fourier transform of AFM evaluation result information in an x-direction (i.e., in a continuous sweep direction of a cantilever), i.e., because the AFM measurement has high reliability in the x-direction, but relatively has difficulty achieving high reliability in the y-direction perpendicular to the x-direction in the same plane mainly due to hysteresis in a piezo element in a dimensional head.

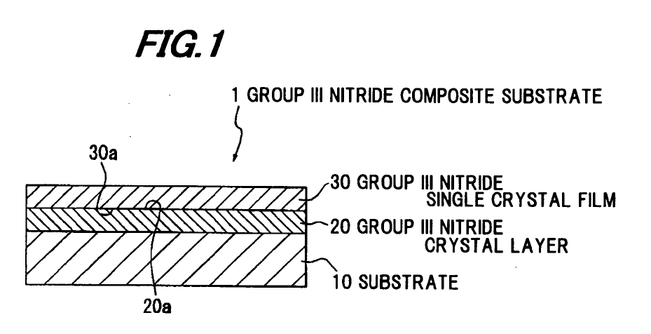

FIG. 1 is a schematic cross-sectional view showing a group III nitride composite substrate in an embodiment according to the invention.

A group III nitride composite substrate 1 in this embodiment comprises a substrate 10 formed of a high melting point conductive material, a group III nitride crystal layer 20 provided on the substrate 10 as a group III nitride layer, and a group III nitride single crystal film 30 provided on the group III nitride crystal layer 20.

Substrate 10

The substrate 10 is formed of a high melting point conductive material whose melting point is as high as not less than 1100° C. The conductive material may use a metal material. The metal material may use e.g., tungsten, whose melting point is 3410° C., and molybdenum, whose melting point is 2610° C. Further, the metal material may use tantalum (melting point: 3000° C.), niobium (melting point: 2468° C.), vanadium (melting point: 1700° C.), nickel (melting point: 1453° C.), titanium (melting point: 1668° C.), chromium (melting point: 1875° C.), zirconium (melting point: 1852° C.), or the like. Also, the substrate 10 can be molded to have a substantially circular shape, substantially rectangular shape, etc. viewed from top. Further, the substrate 10 can, in the case of having a substantially circular shape viewed from top, be sized to have 2-inch, 3-inch, 4-inch, etc. diameter, and in the case of having a substantially rectangular shape viewed from top, be sized to have 2-inch, 3-inch, 4-inch, etc. circumscribed circle diameter. The substrate 10 may be formed of a laminate of mutually different metal materials.

Here, the substrate 10 surface, i.e., the surface contacted with the group III nitride crystal layer 20 may also have an undulation comprising periodic roughness. In such a case, the 1-dimensional power spectral density in the spatial wavelength region of not less than 0.1 (/μm) and less than 1 (/μm) of that undulation is controlled at less than 500 nm³.

Group III Nitride Crystal Layer 20

The group III nitride crystal layer 20 is formed of a group III nitride compound semiconductor expressed by AlₓIn_{y}Ga_{1-x-y}N (0≦x≦1, 0≦y≦1, 0≦x+y≦1). This group III nitride compound semiconductor may use e.g., GaN, indium nitride (InN), aluminum nitride (AlN), Al_{0.1}In_{0.1}Ga_{0.8}N, or the like. Also, the group III nitride crystal layer 20 has an undulation comprising periodic roughness in surface 20a of the group III nitride crystal layer 20 contacted with group III nitride single crystal film 30. Here, the 1-dimensional power spectral density in the spatial wavelength region of not less than 0.1 (/μm) and less than 1 (/μm) of that undulation is controlled at less than 500 nm³ Also, the group III nitride crystal layer 20 may have an undulation analogous to the undulation comprising periodic roughness the surface 20a has. In such a case, the 1-dimensional power spectral density in the spatial wavelength region of not less than 0.1 (/μm) and less than 1 (/μm) of that undulation is also controlled at less than 500 nm³.

Group III Nitride Single Crystal Film 30

The group III nitride single crystal film 30 is formed of a group III nitride compound semiconductor expressed by AlₓIn_{y}Ga_{1-x-y}N (0≦x≦1, 0≦y≦1, 0≦x+y≦1), in the same manner as the group III nitride crystal layer 20. Also, the group III nitride single crystal film 30 has an undulation comprising periodic roughness in surface 30a of the group III nitride single crystal film 30 contacted with the group III nitride crystal layer 20. Here, the 1-dimensional power spectral density in the spatial wavelength region of not less than 0.1 (/μm) and less than 1 (/μm) of that undulation is controlled at 10 less than 500 nm³. Also, the group III nitride single crystal film 30 may have an undulation comprising periodic roughness in opposite, i.e., reverse surface to surface 30a. In such a case, the 1-dimensional power spectral density in the spatial wavelength region of not less than 0.1 (/μm) and less than 1 (/μm) of that undulation is also controlled at less than 500 nm³. Namely, the group III nitride single crystal film 30 in this embodiment has an undulation comprising periodic roughness in both the surface 30a and the reverse surface to the surface 30a.

Group III Nitride Composite Substrate 1 Manufacturing Process

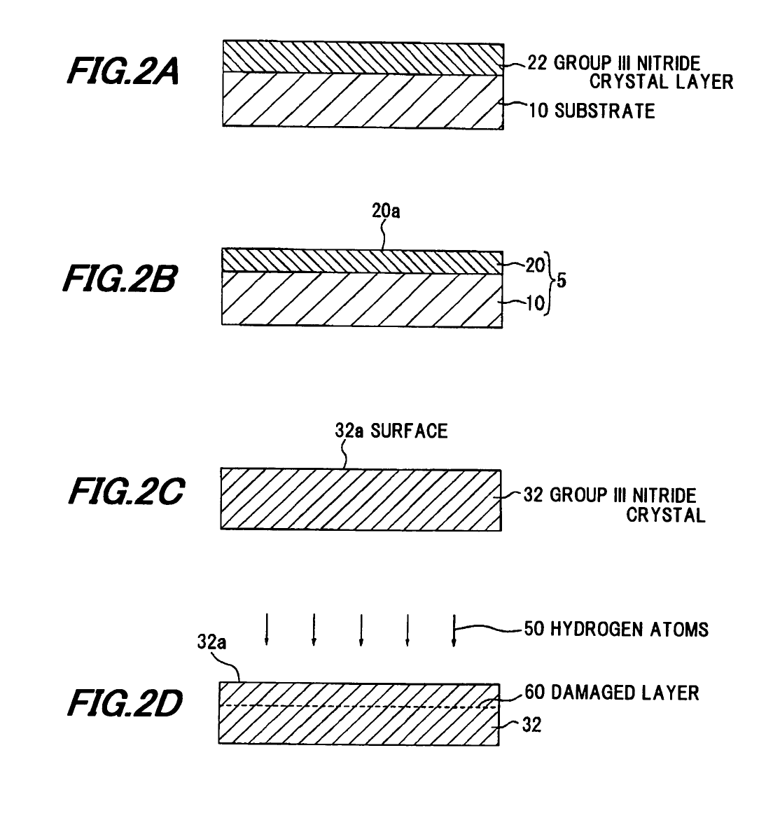

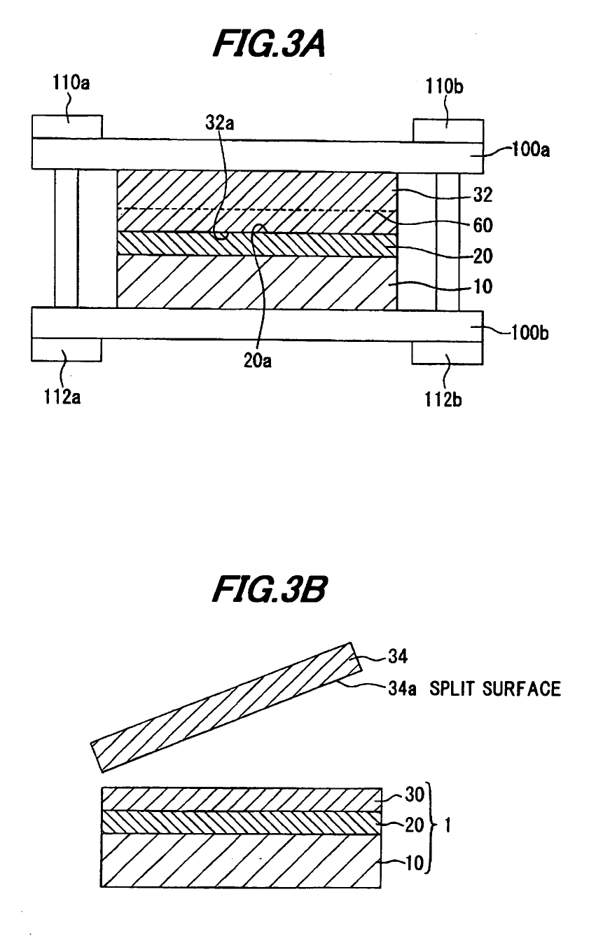

FIGS. 2A-2D and 3A and 3B show one example of a flow for manufacturing a group III nitride composite substrate in an embodiment according to the invention.

As shown in FIG. 2A, there is first prepared a substrate 10 with a group III nitride crystal layer 22 (Substrate-preparing step). Specifically, the group III nitride crystal layer 22 is grown on the substrate 10, using Hydride Vapor Phase Epitaxy (HVPE), Metal Organic Chemical Vapor Deposition (MOCVD), etc.

Subsequently, the group III nitride crystal layer 22 surface is ground (First grinding step). As shown in FIG. 2B, this forms a substrate 5 with group III nitride crystal layer 20 having surface 20a formed with an undulation comprising periodic roughness. Here, the 1-dimensional power spectral density in the spatial wavelength region of not less than 0.1 (/μm) and less than 1 (/μm) of that undulation is less than 500 nm³.

The First grinding step of forming such an undulation in the surface 20a can be implemented as follows. A vacuum suction stage is first prepared. The group III nitride crystal layer 22 side, i.e., the group III nitride crystal layer 22 surface is contacted and vacuum-chucked with the stage, followed by rotation of the substrate (hereinafter referred to as “the work”) comprising the substrate 10 and the group III nitride crystal layer 22 sucked to the stage at a rotation speed on the order of not less than 1000 rpm and not more than 3000 rpm, and supply of a small-viscosity η wax (η<100 cp at 100° C., for example) to the backside of the substrate 10.

The rotation is sustained for 10 sec to 30 sec, to make the thickness of the wax over the work uniform. And the rotation is stopped and the work is then heated (e.g., heated with a lamp), to sufficiently evaporate organic solvent contained in the wax (Wax coating step), followed by turning upside down the work-sucked stage, and pressing the wax-coated surface against a lamination plate heated at not less than 100° C. In this state, the vacuum suction is stopped and the stage is removed. Subsequently, by using an air bag stamp, the work is pressed against the lamination plate on the group III nitride crystal layer 22 side at a pressure of not less than 1 kgf/cm², to fix the work to the lamination plate (Work fixing step). Here, it is preferable that the surface roughness Ra of the lamination plate surface is on the order of not less than 1 μm and not more than 20 μm. Also, it is preferable that the backside of the substrate 10 is ground beforehand so that its surface roughness Ra is on the order of not less than 1 μm and not more than 20 μm.

Subsequently, the surface of the work fixed to the lamination plate, i.e., the group III nitride crystal layer 22 surface is ground using a surface plate (Grinding step), thereby allowing formation of the surface 20a with an undulation comprising periodic roughness. The surface plate uses a metal surface plate (e.g., tin surface plate), which is not deformed elastically. This results in the substrate 5 with group III nitride crystal layer 20.

Next is prepared a group III nitride single crystal 32 as a group III nitride single crystal substrate, as shown in FIG. 2C (Single crystal-preparing step). The group III nitride single crystal 32 is formed of a group III nitride compound semiconductor expressed by AlₓIn_{y}Ga_{1-x-y}N (0≦x≦1, 0≦y≦1, 0≦x+y≦1).

The group III nitride single crystal 32 manufacturing method is as follows: First, using HVPE, a not less than 300 μm-thick low dislocation density group III nitride single crystal layer is grown epitaxially on an underlying substrate such as a sapphire substrate, a GaAs substrate, a GaN substrate, or the like, and then the group III nitride single crystal layer epitaxially grown is separated from the underlying substrate. This results in the group III nitride single crystal 32.

Also, as techniques for reducing the dislocation density of the group III nitride single crystal layer, there are the Pendeoepitaxy method (i.e., the method growing a nitride semiconductor layer on an underlying substrate, using photolithography and dry etching to leave the grown nitride semiconductor or groove the nitride semiconductor layer until exposing the underlying substrate, pattern the nitride semiconductor layer on the underlying substrate, and subsequently from a sidewall of the patterned nitride semiconductor layer, laterally grow the nitride semiconductor), Epitaxial Lateral Overgrowth method (ELO method forming on an underlying substrate a mask with an opening, selectively laterally growing a nitride semiconductor from the opening, and thereby forming a group III nitride single crystal layer with few dislocations), Facet Initiated Epitaxial Lateral Overgrowth method (FIELO method forming on an underlying substrate a silicon oxide mask with an opening, and forming facets in the opening to thereby alter the dislocation propagation direction, to reduce threading dislocations extending from the underlying substrate to an upper surface of an epitaxially grown layer), Facet Controlled Epitaxial Lateral Overgrowth (FACELO method selectively laterally growing a nitride semiconductor, while controlling facet structure at a growing temperature, a growing pressure, etc.), Dislocation Elimination by the Epi-growth with Inverted-Pyramidal Pits method (DEEP method using a silicon oxide mask patterned on a GaAs substrate, growing a group III nitride single crystal, and deliberately forming in the crystal surface plural pits surrounded by facets, to accumulate dislocations at the bottom of the pits and thereby reduce dislocations in other regions excluding the pits), Void-Assisted Separation method (VAS method growing a low dislocation density group III nitride single crystal layer on an underlying sapphire substrate via a thin film having mesh structure comprising a metal nitride such as TiN, to cause voids in the interface between the underlying substrate and group III nitride single crystal to thereby assist in separating the group III nitride single crystal layer), or the like.

Use of the foregoing dislocation density-reducing techniques allows formation of the group III nitride single crystal 32 having a dislocation density of not less than 104 cm⁻² and not more than 10⁷ cm⁻². Also, the X-ray locking curve Full Width at Half Maximum (FWHM) in the (0 0 0 2) plane of this group III nitride single crystal 32 has a crystal quality of not less than 30 arcsec and not more than 300 arcsec.

Here, the group III nitride single crystal 32 has surface 32a with an undulation comprising periodic roughness, formed through the same grinding step (the second grinding step) as the above-mentioned surface 20a-forming step. In other words, the surface 32a has the undulation whose 1-dimensional power spectral density in the spatial wavelength region of not less than 0.1 (/μm) and less than 1 (/μm) is less than 500 nm³. The group III nitride single crystal 32 may have formed in its reverse surface an undulation similar to the undulation the surface 32a has. Namely, the group III nitride single crystal 32 may have the undulation comprising periodic roughness in either or both of the surface 32a and the reverse surface.

This is followed by implantation of specified atoms from the surface 32a to the inside of the group III nitride single crystal 32, to thereby form a damaged layer 60 inside the group III nitride single crystal 32 (Damaged layer-forming step). For example, implanting hydrogen atoms 50 from the surface 32a side into the surface 32a allows the damaged layer 60 to be formed at a depth of a few hundreds of nm from the surface 32a.

As shown in FIG. 3A, next are superimposed the surface 20a of substrate 5 with group III nitride crystal layer 20 and the surface 32a of group III nitride single crystal 32, which are sandwiched and fixed between clamps 100a and 100b. In that case, a set of bolt 110a and nut 112a, and a set of bolt 110b and nut 112b are used to apply an appropriate pressure to the clamps 100a and 100b. It is preferable that the clamps 100a and 100b, bolt 110a and nut 112a, and bolt 110b and nut 112b are formed of molybdenum.

The clamps 100a and 100b holding the surface 20a of substrate 5 with group III nitride crystal layer 20 and the surface 32a of group III nitride single crystal 32 superimposed are placed in an electric furnace, which is filled with hydrogen or nitrogen atmosphere. In the electric furnace, heat treatment is implemented at 700-1000° C. for 30 min. As shown in FIG. 3B, this results in group III nitride composite substrate 1 with the fusion of the surface 20a of substrate 5 with group III nitride crystal layer 20 and the surface 32a of group III nitride single crystal 32 (Fusing step). Also, as shown in FIG. 3B, separation layer 34 with split surface 34a is separated at the damaged layer 60 from the group III nitride composite substrate 1.

In this manner, the group III nitride composite substrate 1 can be fabricated that has no voids or reduced voids at the interface between the group III nitride crystal layer and the group III nitride single crystal film 30.

Separation Layer 34

Here, the split surface 34a of the separation layer 34 of the group III nitride single crystal 32 is a broken surface formed by substantially uniformly implanting hydrogen atoms 50 into the surface 32a of the group III nitride single crystal 32 in which the 1-dimensional power spectral density in the spatial wavelength region of not less than 0.1 (/μm) and less than 1 (/μm) of the undulation formed is less than 500 nm³. Thus, by etching the split surface 34a of the separation layer 34, an undulation comprising periodic roughness can be formed in the split surface 34a of the separation layer 34, the 1-dimensional power spectral density in the spatial wavelength region of not less than 0.1 (/μm) and less than 1 (/μm) of that undulation formed can be less than 500 nm³. That etching is implemented with a mixture of phosphoric acid and sulfuric acid held at not less than 230° C. for the order of 1 hour, for example. The mixture ratio of phosphoric acid and sulfuric acid is 1:1 in volume ratio, as one example. The separation layer 34 etched can be reused as group III nitride single crystal 32 in this embodiment.

Group III nitrides typically have wurtzite structure, and therefore polarity in a c-axis direction. Thus, when manufacturing group III nitride composite substrate 1 by fusing a crystalline plane normal to the c-axis (i.e., c-plane) with substrate 5 with group III nitride crystal layer 20, the hydrogen atoms 50-implanted surface is varied, dependent on which polarity to be exposed at a final group III nitride composite substrate 1 surface (i.e., a principal surface exposed outside of group III nitride single crystal film 30). In other words, which of the surface 32a and the reverse surface of the group III nitride single crystal 32 to be formed with an undulation comprising periodic roughness depends on which polarity to be exposed at a final group III nitride composite substrate 1 surface.

That is, when fabricating a group III polar face substrate, its N-polar face is exposed at surface 32a of group III nitride single crystal 32, and is formed with an undulation comprising periodic roughness. Hydrogen atoms 50 implantation is performed from the N-polar face side having the undulation. On the other hand, when fabricating a group V polar face substrate, its Ga-polar face is exposed at surface 32a of group III nitride single crystal 32, and is formed with an undulation comprising periodic roughness. Hydrogen atoms 50 implantation is performed from the Ga-polar face side having the undulation. Also, when fabricating a R-face substrate, or a (1 1-2 2) face substrate, because of a polarity difference between its frontside and backside surfaces, hydrogen atoms implantation is performed from a specified surface side, taking the polarity difference between the frontside and backside surfaces into consideration. However, when fabricating an M face substrate, or an a-face substrate, because of no polarity in a direction normal to the substrate, no such consideration is required. On the other hand, when using group III nitride single crystal 32 provided with a c-axis direction component of an off-angle, because of a polarity difference between its frontside and backside surfaces, the hydrogen atoms 50-implanted surface can be determined, based on which of the frontside and backside surfaces to be exposed at the final group III nitride composite substrate 1 surface in the same manner as above.

### Advantages of the Embodiment

Since the group III nitride composite substrate 1 in this embodiment is formed with an undulation whose 1-dimensional power spectral density in the spatial wavelength region of not less than 0.1 (/μm) and less than 1 (/μm) is less than 500 nm³ in both the surface 20a of group III nitride crystal layer 20 and the surface 30a of group III nitride single crystal film 30, the occurrence of voids at the laminated interface can be reduced. This allows separation at the laminated interface to be inhibited even if mechanically processing, e.g., grinding the group III nitride composite substrate 1, and also even if increasing/decreasing the temperature between room temperature and a high temperature, e.g., 1000° C.

Namely, the group III nitride composite substrate 1 in this embodiment can be used in group III nitride semiconductor device fabrication, and provided as a group III nitride composite substrate 1 whose diameter is as large as not less than 2 inches, because of having the laminated interface formed taking long period roughness into consideration.

Since the group III nitride composite substrate 1 in this embodiment allows the not less than 2 inch-diameter and high quality group III nitride semiconductor single crystal to be fused with inexpensive substrate 5 with group III nitride crystal layer 20 inhibiting the occurrence of voids, it is possible to provide the high quality group III nitride composite substrate 1 inexpensively. Since the group III nitride composite substrate 1 in this embodiment allows separation at the laminated interface to be inhibited, the electrical conduction and thermal conduction at that laminated interface can be good.

Also, since the group III nitride composite substrate 1 in this embodiment uses substrate 10 formed of a high melting point conductive material, the group III nitride composite substrate 1 can be used in group III nitride semiconductor device fabrication in which a relatively high temperature, a few hundreds of ° C. heat treatment step is included in the device fabrication process. As the group III nitride semiconductor device, there are high-output laser diodes, high-intensity light-emitting diodes, or high-frequency electronic devices, for example.

### EXAMPLES

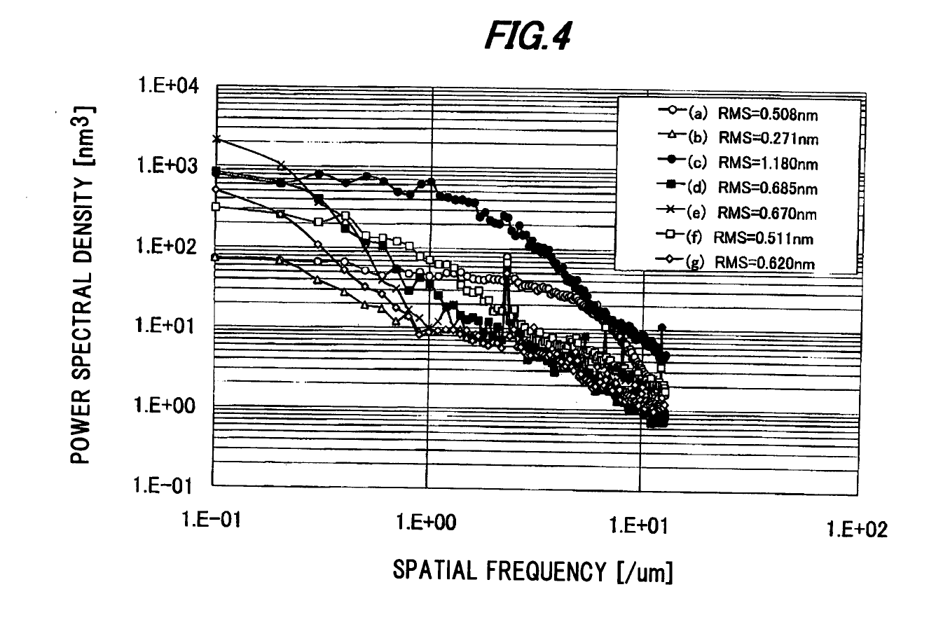

FIG. 4 shows the results of power spectral density analysis of group III nitride composite substrates in Examples and Comparative Examples.

For each of below-described Examples 1-3 and Comparative Examples 1-3, AFM measurement is done in a 10 μm×10 μm range of a group III nitride composite substrate fabricated. The graphs shown in FIG. 4 are the results of power spectral density analysis based on the results of the measurement. In FIG. 4, the horizontal axis is the spatial frequency (/μm), and the vertical axis is the power spectral density (nm³). Also, Table 1 shows values for main points of the points shown in FIG. 4.

TABLE 1

| | | Power spectral density (nm³) | | | | | | |
|---|---|---|---|---|---|---|---|---|
| | | | | | | Comparative | Comparative | Comparative |
| | | Example 1 | Example 1 | Example 2 | Example 3 | Example 1 | Example 2 | Example 3 |
| | | Graph (a) | Graph (b) | Graph (f) | Graph (g) | Graph (c) | Graph (d) | Graph (e) |
| Spatial | 0.1 | 72.6 | 73.9 | 307 | 498.6 | 801 | 854 | 2101 |
| frequency | 0.4 | 66.8 | 27.7 | 249 | 52.5 | 632 | 172 | 227 |
| (/μm) | 0.7 | 55.7 | 12.1 | 121 | 17.7 | 497 | 54.8 | 30.8 |
| | 1.0 | 44.5 | 9.7 | 720 | 8.78 | 662 | 35.4 | 10.1 |
| | 3.0 | 35.0 | 4.98 | 9.37 | 4.64 | 130 | 6.49 | 6.10 |
| | 5.0 | 23.1 | 3.76 | 6.86 | 4.09 | 31.7 | 4.40 | 5.96 |
| | 7.0 | 11.7 | 2.31 | 3.80 | 1.95 | 12.0 | 1.84 | 3.66 |
| | 10.0 | 3.25 | 1.42 | 2.48 | 1.63 | 7.88 | 1.17 | 2.37 |
| | 12.8 | 1.57 | 1.08 | 1.73 | 1.20 | 4.92 | 0.852 | 1.84 |

Below are described Examples 1-3 and Comparative Examples 1-3 in detail.

### Example 1

Group III nitride composite substrate 1 in Example 1 is fabricated based on the manufacturing method explained in the embodiment as follows: First, using HVPE, a 100 μm-thick GaN polycrystalline layer is deposited on a 2-inch diameter molybdenum substrate. Here, the reverse surface Ra of the molybdenum substrate is ground to be 3 μm. Subsequently, the polycrystalline layer deposited is mirror-ground to be 10 μm thick. This results in the substrate with the group III nitride crystal layer in Example 1.

Here, the grinding conditions are as follows: First, using a wax with a viscosity of 60 cp at 100° C., the wax-coating step is implemented. In the work-fixing step following the wax-coating step, the temperature of laminating the work to a lamination plate is set at 100° C. Here, the work is fixed to the lamination plate at the pressure of 3 kgf/cm². The lamination plate used has 10 μm surface Ra. A tin surface plate is used in the grinding step.

Power spectral density analysis is done for surface of the substrate with the group III nitride crystal layer obtained in Example 1. As shown by (a) in FIG. 4, its results are that the power spectral density is 72.6 (nm³) at the spatial frequency of 0.1 (/μm), the power spectral density is 44.5 (nm³) at the spatial frequency of 1.0 (/μm), and the power spectral density is 1.57 (nm³) at the spatial frequency of 12.8 (/μm), for example.

Subsequently, a 2 inch-diameter and 5 mm-thick GaN single crystal (specifically, a single crystal whose crystalline axis in its thickness direction is the c-axis) is prepared, and the N-polar face of this GaN single crystal is ground in the same conditions as the above grinding conditions. AFM evaluation is done of power spectral density of that ground surface. As shown by (b) in FIG. 4, its results are that the power spectral density is 73.9 (nm³) at the spatial frequency of 0.1 (/μm), the power spectral density is 9.7 (nm³) at the spatial frequency of 1.0 (/μm), and the power spectral density is 1.08 (nm³) at the spatial frequency of 12.8 (/μm), for example.

This is followed by implanting a hydrogen atom dose of 3×10¹⁷ cm⁻² at 50 keV at room temperature into this N-polar face ground of the GaN single crystal. Subsequently, the GaN single crystal with the N-polar face after the hydrogen atom implantation, and the surface of the substrate with the group III nitride crystal layer in Example 1 are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in the 2 inch-diameter group III nitride composite substrate in Example 1 in which the group III nitride crystal layer is sandwiched between the GaN single crystal film with its Ga-polar face serving as a principal surface and molybdenum substrate 10.

### Comparative Example 1

Power spectral density analysis is done for split surface of the GaN single crystal (i.e., separation layer) separated in Example 1. As shown by (c) in FIG. 4, its results are that the power spectral density is 801 (nm³) at the spatial frequency of 0.1 (/μm), the power spectral density is 662 (nm³) at the spatial frequency of 1.0 (/μm), and the power spectral density is 4.92 (nm³) at the spatial frequency of 12.8 (/μm), for example.

This is followed by implanting a hydrogen atom dose of 3×10¹⁷ cm² at 50 keV at room temperature into this split surface of the GaN single crystal. Subsequently, the surface of a substrate with a group III nitride crystal layer provided with a GaN layer on molybdenum substrate 10 prepared in the same manner as in Example 1 and the split surface of the GaN single crystal are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in a 2 inch-diameter group III nitride composite substrate in Comparative Example 1 in which the group III nitride crystal layer is sandwiched between the GaN single crystal film with its Ga-polar face serving as a principal surface and molybdenum substrate 10.

### Comparative Example 2

A group III nitride composite substrate in Comparative Example 2 is fabricated as follows: First, using HVPE, a 100 μm-thick GaN polycrystalline layer is deposited on a 2-inch diameter molybdenum substrate. Here, the reverse surface Ra of the molybdenum substrate is ground to be 0.1 μm. Subsequently, the polycrystalline layer deposited is mirror-ground to be 10 μm thick. This results in the substrate with the group III nitride crystal layer in Comparative Example 2.

Here, the grinding conditions are as follows: First, using a wax with a viscosity of 1300 cp at 100° C., the wax-coating step is implemented. In the work-fixing step following the wax-coating step, the temperature of laminating the work to a lamination plate is set at 70° C. Here, the work is fixed to the lamination plate at the pressure of 0.9 kgf/cm². The lamination plate used has 0.1 μm surface Ra. A resin surface plate is used in the grinding step.

Power spectral density analysis is done for surface of the substrate with the group III nitride crystal layer obtained in Comparative Example 2. As shown by (d) in FIG. 4, its results are that the power spectral density is 854 (nm³) at the spatial frequency of 0.1 (/μm), the power spectral density is 35.4 (nm³) at the spatial frequency of 1.0 (/μm), and the power spectral density is 0.852 (nm³) at the spatial frequency of 12.8 (/μm), for example.

Subsequently, a 2 inch-diameter and 5 mm-thick GaN single crystal (specifically, a single crystal whose crystalline axis in its thickness direction is the c-axis) is prepared, and the N-polar face of this GaN single crystal is ground in the same manner as in Example 1. This is followed by implanting a hydrogen atom dose of 3×10¹⁷ cm⁻² at 50 keV at room temperature into the ground N-polar face of the GaN single crystal. Subsequently, the GaN single crystal with the N-polar face after the hydrogen atom implantation, and the surface of the substrate with the group III nitride crystal layer in Comparative Example 2 are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in the 2 inch-diameter group III nitride composite substrate in Comparative Example 2 in which the group III nitride crystal layer is sandwiched between the GaN single crystal film with its Ga-polar face serving as a principal surface and molybdenum substrate 10.

### Comparative Example 3

A 2 inch-diameter and 5 mm-thick GaN single crystal (specifically, a single crystal whose crystalline axis in its thickness direction is the c-axis) is prepared, and the N-polar face of this GaN single crystal is ground in the following grinding conditions: First, using a wax with a viscosity of 1300 cp at 100° C., the wax-coating step is implemented. In the work-fixing step following the wax-coating step, the temperature of laminating the work to a lamination plate is set at 70° C. Here, the work is fixed to the lamination plate at the pressure of 0.9 kgf/cm². The reverse surface Ra of the molybdenum substrate, and the surface Ra of the lamination plate used are 0.1 μm thick. A resin surface plate is used in the grinding step.

Subsequently, power spectral density analysis using AFM is done in a 10 μm×10 μm range of the ground surface. As shown by (e) in FIG. 4, its results are that the power spectral density is 2101 (nm³) at the spatial frequency of 0.1 (/μm), the power spectral density is 10.1 (nm³) at the spatial frequency of 1.0 (/μm), and the power spectral density is 1.84 (nm³) at the spatial frequency of 12.8 (/μm), for example.

This is followed by implanting a hydrogen atom dose of 3×10¹⁷ cm⁻² at 50 keV at room temperature into the ground surface. Subsequently, the GaN single crystal with the ground surface after the hydrogen atom implantation, and the surface of the substrate formed with the polycrystalline GaN layer on the molybdenum substrate prepared in the same manner as in Example 1 are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in a 2 inch-diameter group III nitride composite substrate in Comparative Example 3 in which the group III nitride crystal layer is sandwiched between the GaN single crystal film with its Ga-polar face serving as a principal surface and molybdenum substrate 10.

### Example 2

Etching is done on split surface of the GaN single crystal (i.e., separation layer) separated in Example 1. The etching uses a mixture of phosphoric acid and sulfuric acid (composition 1:1) at 230° C. as an etchant, and is implemented for 1 hour. AFM evaluation is done of power spectral density of the etched split surface. As shown by (f) in FIG. 4, its results are that the power spectral density is 307 (nm³) at the spatial frequency of 0.1 (/μm), the power spectral density is 72.0 (nm³) at the spatial frequency of 1.0 (/μm), and the power spectral density is 1.73 (nm³) at the spatial frequency of 12.8 (/μm), for example.

This is followed by implanting a hydrogen atom dose of 3×10¹⁷ cm² at 50 keV at room temperature into the etched split surface. Subsequently, the surface of a substrate with a group III nitride crystal layer provided with a GaN layer on molybdenum substrate 10 prepared in the same manner as in Example 1 and the etched split surface of the GaN single crystal are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in a 2 inch-diameter group III nitride composite substrate in Example 2 in which the group III nitride crystal layer is sandwiched between the GaN single crystal film with its Ga-polar face serving as a principal surface and molybdenum substrate 10.

### Example 3

A 2 inch-diameter and 5 mm-thick GaN single crystal (specifically, a single crystal whose crystalline axis in its thickness direction is the c-axis) is prepared, and the Ga-polar face of this GaN single crystal is ground in the following grinding conditions: First, using a wax with a viscosity of 60 cp at 100° C., the wax-coating step is implemented. In the work-fixing step following the wax-coating step, the temperature of laminating the work to a lamination plate is set at 100° C. Here, the work is fixed to the lamination plate at the pressure of 3 kgf/cm². The reverse surface Ra of the molybdenum substrate used is 3 μm thick, and the surface Ra of the lamination plate used are 10 μm thick. A tin surface plate is used in the grinding step.

Subsequently, power spectral density analysis using AFM is done in a 10 μm×10 μm range of the ground surface. As shown by (g) in FIG. 4, its results are that the power spectral density is 499 (nm³) at the spatial frequency of 0.1 (/μm), the power spectral density is 8.78 (nm³) at the spatial frequency of 1.0 (/μm), and the power spectral density is 1.20 (nm³) at the spatial frequency of 12.8 (/μm), for example.

This is followed by implanting a hydrogen atom dose of 3×10¹⁷ cm⁻² at 50 keV at room temperature into the ground surface. Subsequently, the GaN single crystal with the ground surface after the hydrogen atom implantation, and the surface of the substrate formed with the polycrystalline GaN layer on the molybdenum substrate prepared in the same manner as in Example 1 are superimposed, and fixed at the pressure of 50 kgf/cm² with clamps, and in this state, placed in an electric furnace, which are heated in a nitrogen atmosphere at 800° C. for 30 min. Following the heat treatment, the superimposed substrate is cooled to room temperature, and taken out of the electric furnace, and when removing the clamps, separated into a group III nitride composite substrate and a separation layer at a damaged layer formed by the hydrogen atom implantation. This results in a 2 inch-diameter group III nitride composite substrate in Example 3 in which the group III nitride crystal layer is sandwiched between the GaN single crystal film with its Ga-polar face serving as a principal surface and molybdenum substrate 10.

Effects of Annealing

For each of the group III nitride composite substrates fabricated in Examples 1-3 and Comparative Examples 1-3 in which the group III nitride crystal layer is sandwiched between the GaN single crystal film with its Ga-polar face serving as a principal surface and molybdenum substrate 10, annealing is done in a mixture of hydrogen, nitrogen, and ammonia atmospheres, at 1000° C. for 1 hour. Table 2 shows the results of observing the interface of each annealed group III nitride composite substrate (i.e., the interface between the group III nitride crystal layer and the group III nitride single crystal film).

TABLE 2

| | | | | Comparative | Comparative | Comparative |
|---|---|---|---|---|---|---|
| | Example 1 | Example 2 | Example 3 | Example 1 | Example 2 | Example 3 |
| Gallium droplet | None | None | None | Occur | Occur | Occur |
| Cracking | None | None | None | Occur | Occur | Occur |
| Film peeling-off | | | | | | |

Referring to Table 2, the group III nitride composite substrates in Examples 1-3 have no gallium droplets, cracks, and film peeling-off at the interface. On the other hand, the group III nitride composite substrates in Comparative Examples 1-3 cause gallium droplets, cracks, and film peeling-off at the interface.

In the group III nitride composite substrates, a group III nitride device structure is fabricated on the group III nitride single crystal film. Accordingly, it is shown that the annealed group III nitride composite substrates in Examples 1-3, which cause no gallium droplets, cracks, and film peeling-off at the interface, are suitable for group III nitride device fabrication. That is, the group III nitride composite substrates in Examples 1-3 can inhibit the occurrence of gallium droplets between the substrate 10 and the group III nitride crystal layer 20, and between the group III nitride crystal layer 20 and the group III nitride single crystal film 30, even at a high temperature exceeding 900° C., for example. Further, the group III nitride composite substrates in Examples 1-3 can inhibit cracking and film peeling-off at the laminated interface between the group III nitride crystal layer 20 and the group III nitride single crystal film 30. And the group III nitride composite substrates in Examples 1-3 can inhibit film peeling-off at that laminated interface, even when processed mechanically.

Subsequently, mirror-grinding is done on surface of each group III nitride composite substrate in Examples 1-3 and Comparative Examples 1-3. The group III nitride composite substrates in Examples 1-3 can be processed without difficulty. On the other hand, the group III nitride composite substrates in Comparative Examples 1-3 cause cracks, and film peeling-off at the interface.

From the foregoing, it is shown that the group III nitride composite substrates in Examples 1-3 can be used in group III nitride device fabrication.

### Example 4

Group III nitride composite substrates, in which the material constituting group III nitride crystal layer 20 and group III nitride single crystal film 30 are substituted with InN, AlN, and Al_{0.1}In_{0.1}Ga_{0.8}N, are also examined in the same manner as in Examples 1-3. It has been verified that their results similar to those of the group III nitride composite substrates in Examples 1-3 can be obtained.

The group III nitride composite substrates in Examples 1-3 and the group III nitride composite substrates in Comparative Examples 1-3 are compared referring to FIG. 4. Comparing FIG. 4, Examples (b), (f) and (g), and Comparative Example (e), no marked differences are seen in the high spatial frequency region exceeding 1 (/μm) and of not more than 12.8 (/μm). In the low spatial frequency region of not less than 0.1 (/μm) and not more than 1 (/μm), however, marked differences in power spectral density are verified. Referring to FIG. 4, it is shown that in the spatial frequency range of not less than 0.1 (/μm) and not more than 1 (/μm), group III nitride composite substrates included in the 1-dimentional power spectral density range of not less than 8 nm³ and not more than 498.6 nm³ can be used in group III nitride device fabrication. The smaller the power spectral density in that spatial frequency range, the more ideal the group III nitride composite substrate obtained.

When handling the group III nitride composite substrates in Examples 1-3 using an automatic carrier machine, there is no malfunction in recognition of the group III nitride composite substrates. The reason for this is considered as follows: When surface to be recognized by the automatic carrier machine has many long wavelength components of the spatial frequencies, applying position-detecting laser to that surface may cause the laser reflected at that surface to be not properly received by a light-receiving portion of the automatic carrier machine. However, because the surface of the group III nitride single crystal film exposed at the surface of the group III nitride composite substrates in Examples 1-3 has an undulation comprising periodic roughness, there are few long wavelength components of the spatial frequencies in that surface. Accordingly, it is considered because applying position-detecting laser to that surface of the group III nitride composite substrates in Examples 1-3 allows the laser reflected at that surface to be properly received by the light-receiving portion of the automatic carrier machine.

Although the invention has been described with respect to the above embodiments, the above embodiments are not intended to limit the appended claims. Also, it should be noted that not all the combinations of the features described in the above embodiments are essential to the means for solving the problems of the invention.

What is claimed is:

1. A group III nitride semiconductor composite substrate, comprising:
a substrate comprising a conductive material having a melting point of not less than 1100° C.;
a group III nitride layer provided on the substrate; and
a group III nitride single crystal film provided on the group III nitride layer, wherein the group III nitride layer comprises an undulation comprising a periodic roughness in a surface of the group III nitride layer contacted with the group III nitride single crystal film, and
the undulation comprises a 1-dimensional power spectral density of less than 500 nm³ in a spatial wavelength region of not less than 0.1 (/μm) and less than 1 (/μm).

2. The group III nitride semiconductor composite substrate according to claim 1, wherein
the group III nitride single crystal film comprises an undulation comprising a periodic roughness in a surface of the group III nitride single crystal film contacted with the group III nitride layer, and
the undulation comprises a 1-dimensional power spectral density of less than 500 nm³ in a spatial wavelength region of not less than 0.1 (/μm) and less than 1 (/μm).

3. The group III nitride semiconductor composite substrate according to claim 2, wherein
the substrate comprises a material selected from a group consisting of tungsten, molybdenum, tantalum, niobium, vanadium, nickel, titanium, chromium, and zirconium, and
the group III nitride layer and the group III nitride single crystal film each comprises a group III nitride compound semiconductor having a composition expressed by AlₓIn_{y}Ga_{1-x-y}N (0≦x≦1, 0≦y≦1, 0≦x+y≦1).

4. The group III nitride semiconductor composite substrate according to claim 3, further comprising:
a diameter of not less than 2 inches.

5. A group III nitride semiconductor substrate, comprising:
a frontside surface and a backside surface,
wherein either or both of the frontside surface and the backside surface comprise an undulation comprising a periodic roughness, and
the undulation comprises a 1-dimensional power spectral density of less than 500 nm³ in a spatial wavelength region of not less than 0.1 (/μm) and less than 1 (/μm).

6. The group III nitride semiconductor substrate according to claim 5, wherein
the group III nitride semiconductor substrate comprises a group III nitride compound semiconductor having a composition expressed by AlₓIn_{y}Ga_{1-x-y}N (0≦x≦1, 0≦y≦1, 0≦x+y≦1).

7. A group III nitride semiconductor composite substrate manufacturing method, comprising:
preparing a substrate comprising a group III nitride layer;
grinding a surface of the group III nitride layer of the substrate;
preparing a group III nitride single crystal;
grinding a surface of the group III nitride single crystal;
implanting atoms from a surface of the group III nitride single crystal into the group III nitride single crystal, to thereby form a damaged layer inside the group III nitride single crystal; and
fusing the ground surface of the group III nitride layer of the substrate, and the ground surface of the group III nitride single crystal,
wherein the ground surface of the group III nitride layer, and the ground surface of the group III nitride single crystal each comprise an undulation comprising a periodic roughness, and
the undulation comprises a 1-dimensional power spectral density of less than 500 nm³ in a spatial wavelength region of not less than 0.1 (/μm) and less than 1 (/μm).
